(19) United States
(12) Patent Application Publication
(10) Pub. No.: US 2025/0253615 A1
(43) Pub. Date: Aug. 7, 2025

(54) LIGHT EMITTING DEVICE

(71) Applicant: CANON KABUSHIKI KAISHA, Tokyo (JP)

(72) Inventors: TATSURO UCHIDA, Tokyo (JP); TAKESHI UCHIDA, Kanagawa (JP); TAKAKO SUGA, Kanagawa (JP)

(21) Appl. No.: 19/036,768

(22) Filed: Jan. 24, 2025

(30) Foreign Application Priority Data
Feb. 7, 2024 (JP) 2024-016927

(51) Int. Cl. H01S 5/026; H01S 5/028; H01S 5/183; H01S 5/42

(52) U.S. Cl. CPC H01S 5/0261; H01S 5/028; H01S 5/18344; H01S 5/423

(57) ABSTRACT

A light emitting device includes a plurality of light emitting elements and a plurality of driving wirings for driving the plurality of light emitting elements. The plurality of light emitting elements are divided into a plurality of groups each including at least two light emitting elements, the plurality of driving wirings are provided corresponding to the plurality of groups, the plurality of driving wirings overlap each other at least a part thereof in a plan view, and is electrically separated from each other by an insulating layer, and each of the plurality of driving wirings is electrically connected to light emitting elements belonging to the corresponding group among the plurality of groups on upper surfaces of the light emitting elements.

### BACKGROUND

### Technical Field

The present disclosure relates to a light emitting device.

### Description of the Related Art

A light emitting device in which surface emitting laser (vertical cavity surface emitting laser (VCSEL)) elements are two-dimensionally arranged has been developed as a light source device of such as a light detection and ranging (LiDAR) system or a three-dimensional (3D) sensor. For example, in a ranging device, studies have been made to arrange VCSEL elements having a wide emission diameter at a high density (narrow pitch) for the purpose of improving the performance of distance measurement (e.g., increasing the sensitivity, resolution, and range of distance measurement) and reducing the size of the light source device.

As a driving method of a light source device of a LiDAR system using the VCSEL elements, there are a flash method in which all VCSEL elements constituting an array collectively emit light to perform ranging of a wide area at one time, and a sequential flash method in which a plurality of light emitting regions constituting an array sequentially emits light.

For example, in the sequential flash method, it is possible to improve the distance measurement performance by making the optical power density of a part of the light emitting region of the plurality of light emitting regions equal to the optical power density of the entire device.

Japanese Patent Application Laid-Open No. 2022-165805 describes a light emitting device including a plurality of VCSEL groups that can operate individually. In Japanese Patent Application Laid-Open No. 2022-165805, electrodes connected to the VCSEL groups are arranged on a side of a short side of a substrate on which the light emitting portions are arranged to reduce the size of the light emitting device.

In order to individually emit light in each of the light emitting regions in which the plurality of light emitting elements are arranged, individual driving wirings for controlling each of the light emitting regions are required. However, the space in the light emitting region for laying down the driving wiring is limited, and it is difficult to achieve both the high density of the light emitting elements and the increase in the number of the driving wirings. In addition, since a high current injection value is required to cause a light emitting region including a plurality of light emitting elements to emit light, it is required to increase the limiting current density by increasing the width of the interconnection as much as possible from the viewpoint of avoiding disconnection due to electromigration of the driving wiring. Also from this viewpoint, it is difficult to achieve both high density of the light emitting elements and increase in the number of driving wirings.

### SUMMARY

An object of the present disclosure is to provide a technique suitable for increasing the output and density of the light emitting elements in a light emitting device including a plurality of light emitting element groups which can be driven individually.

According to an embodiment of the present specification, there is provided a light emitting device including a plurality of light emitting elements, and a plurality of driving wirings configured to drive the plurality of light emitting elements, wherein the plurality of light emitting elements are divided into a plurality of groups each including at least two light emitting elements, wherein the plurality of driving wirings are provided corresponding to the plurality of groups, wherein the plurality of driving wirings overlap each other at least a part thereof in a plan view, and is electrically separated from each other by an insulating layer, wherein each of the plurality of driving wirings is electrically connected to light emitting elements belonging to the corresponding group among the plurality of groups on upper surfaces of the light emitting elements, wherein a first driving wiring among the plurality of driving wirings is electrically connected to light emitting elements belonging to a first group among the plurality of groups, and is not electrically connected to light emitting elements belonging to a second group among the plurality of groups, wherein a second driving wiring among the plurality of driving wirings is not electrically connected to the light emitting elements belonging to the first group, and is electrically connected to the light emitting elements belonging to the second group, and wherein the first driving wiring extends over the upper surfaces of the light emitting elements belonging to the second group.

Further features of the present invention will become apparent from the following description of exemplary embodiments with reference to the attached drawings.

### BRIEF DESCRIPTION OF THE DRAWINGS

FIG. 1 is a schematic plan view illustrating a schematic configuration of a light emitting device according to a first embodiment.

FIG. 2A and FIG. 2B are schematic cross-sectional views illustrating a schematic configuration of the light emitting device according to the first embodiment.

FIG. 3A, FIG. 3B, and FIG. 3C are partial cross-sectional views of the light emitting device according to the first embodiment.

FIG. 4A and FIG. 4B are schematic cross-sectional views illustrating a schematic configuration of a light emitting device according to a modification of the first embodiment.

FIG. 5 and FIG. 6 are schematic plan views illustrating a schematic configuration of a light emitting device according to a modification of the first embodiment.

FIG. 7A and FIG. 7B are schematic cross-sectional views illustrating a schematic configuration of a light emitting device according to a second embodiment.

FIG. 8 is a schematic plan view illustrating a schematic configuration of a light emitting device according to a third embodiment.

FIG. 9A and FIG. 9B are schematic cross-sectional views illustrating a schematic configuration of the light emitting device according to the third embodiment.

FIG. 10A, FIG. 10B, FIG. 10C, and FIG. 10D are partial cross-sectional views of the light emitting device according to the third embodiment.

FIG. 11A, FIG. 11B, FIG. 12A, FIG. 12B, FIG. 12C, and FIG. 12D are partial cross-sectional views of a light emitting device according to a modification of the third embodiment.

FIG. 13 is a schematic plan view illustrating a schematic configuration of a light emitting device according to a fourth embodiment.

FIG. 14A and FIG. 14B are schematic cross-sectional views illustrating a schematic configuration of the light emitting device according to the fourth embodiment.

FIG. 15 is a schematic plan view illustrating a schematic configuration of a light emitting device according to a fifth embodiment.

FIG. 16 is a block diagram illustrating a schematic configuration of a ranging device according to a sixth embodiment.

FIG. 17A and FIG. 17B are block diagrams illustrating a configuration example of a moving object according to a seventh embodiment.

### DESCRIPTION OF THE EMBODIMENTS

Hereinafter, embodiments of the present invention will be described with reference to the drawings. Note that the following embodiments do not limit the invention according to the claims. Although a plurality of features are described in the embodiments, not all of the plurality of features are essential to the invention, and the plurality of features may be arbitrarily combined. Further, in the accompanying drawings, the same or similar components are denoted by the same reference numerals, and redundant description will be appropriately omitted. Furthermore, the drawings are merely described for the purpose of describing the structure or configuration, and the dimensions of each member illustrated in the drawings do not necessarily reflect the actual dimensions.

In the following embodiments, a light emitting device in which a plurality of surface emitting laser (vertical cavity surface emitting laser (VCSEL)) elements are two-dimensionally arranged will be described as an example of a light emitting device to which the present invention may be applied. However, the present invention is also applicable to a light emitting device in which other light emitting elements such as light emitting diodes (LEDs) are two-dimensionally arranged.

### First Embodiment

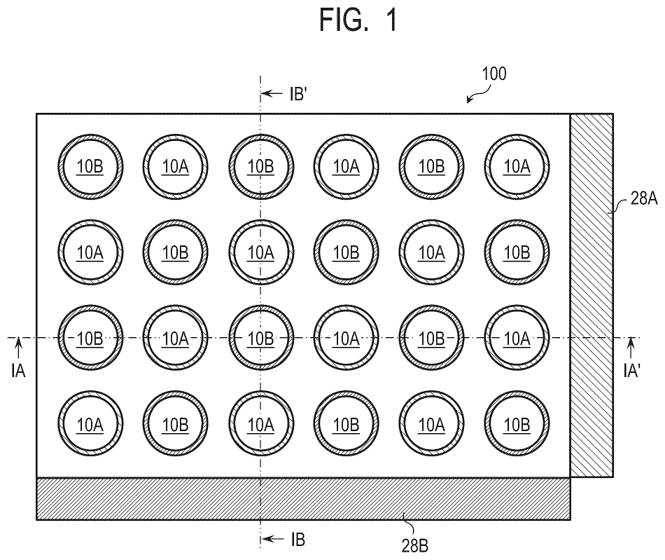

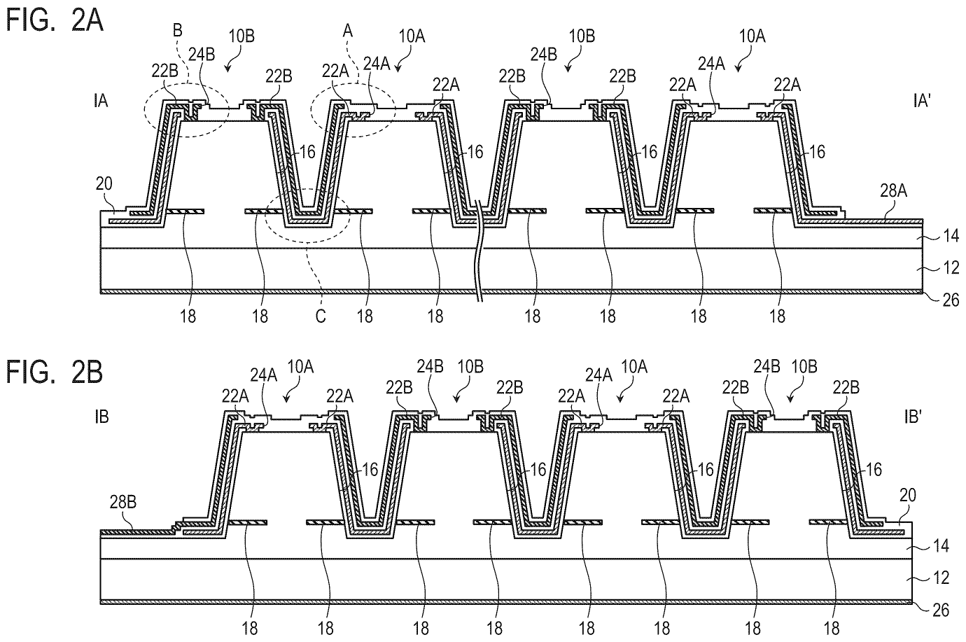

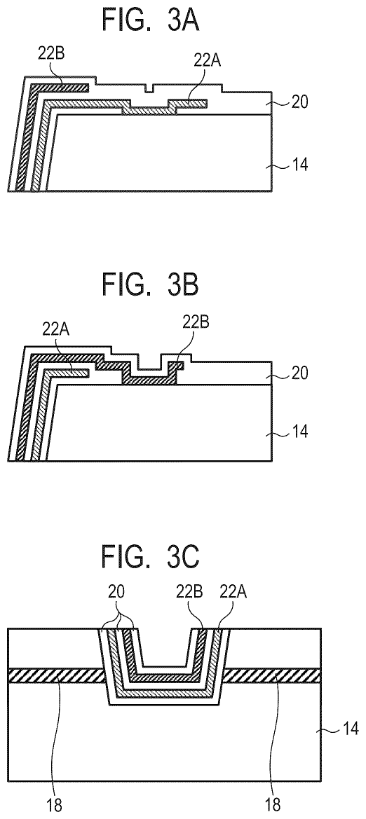

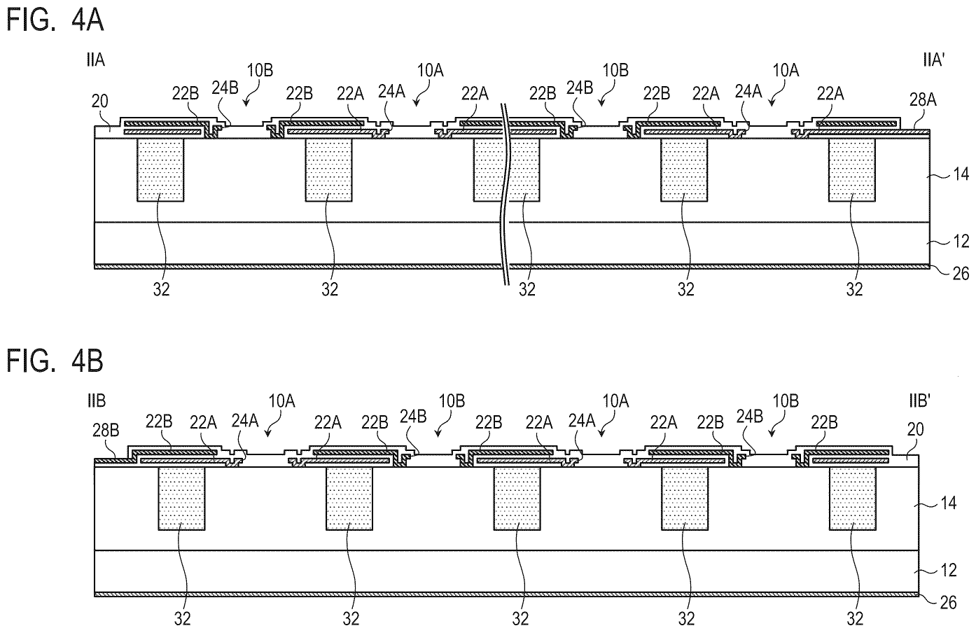

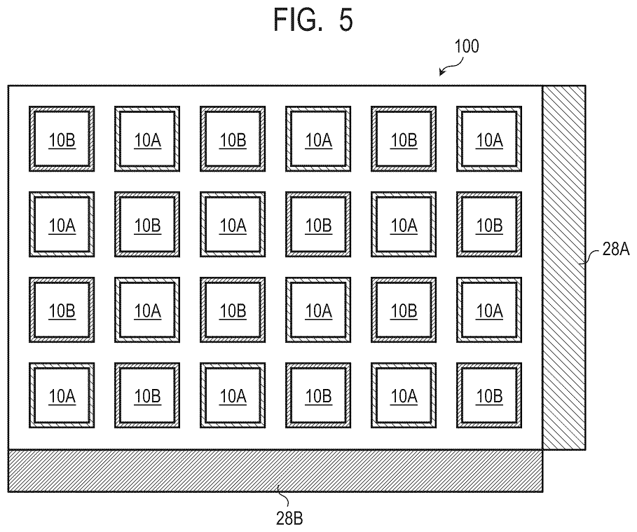

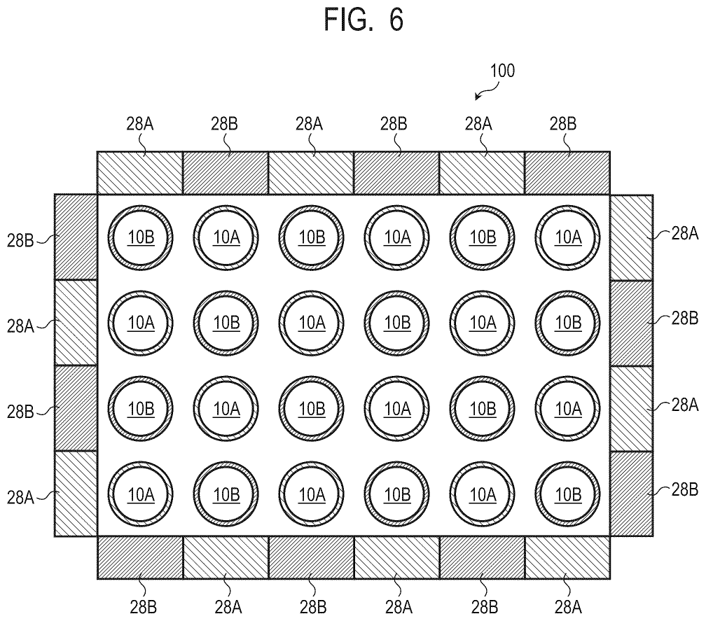

A light emitting device according to a first embodiment of the present invention will be described with reference to FIG. 1 to FIG. 6. FIG. 1 is a schematic plan view illustrating a schematic configuration of a light emitting device according to the present embodiment. FIG. 2A and FIG. 2B are schematic cross-sectional views illustrating a schematic configuration of the light emitting device according to the present embodiment. FIG. 3A to FIG. 3C are partial cross-sectional views of the light emitting device according to the present embodiment. FIG. 4A and FIG. 4B are schematic cross- sectional views illustrating a schematic configuration of a light emitting device according to a modification of the present embodiment. FIG. 5 and FIG. 6 are schematic plan views illustrating a schematic configuration of a light emitting device according to a modification of the present embodiment.

The light emitting device 100 according to the present embodiment is a surface emitting semiconductor light emitting device in which a plurality of light emitting elements are two-dimensionally arranged. Each of the plurality of light emitting elements is comprised of a VCSEL element. FIG. 1 is a plan view of the light emitting device 100 as viewed from the light emitting surface side, FIG. 2A is a cross-sectional view taken along line IA-IA′ of FIG. 1, and FIG. 2B is a cross-sectional view taken along line IB-IB′ of FIG. 1. FIG. 3A is an enlarged view of a region A in FIG. 2A, FIG. 3B is an enlarged view of a region B in FIG. 2A, and FIG. 3C is an enlarged view of a region C in FIG. 2A.

FIG. 1 illustrates 24-number of VCSEL elements 10 arranged in a square lattice of (4 rows)×(6 columns) as an example of the plurality of light emitting elements. Each of the 24-number of circular regions illustrated in FIG. 1 represents the VCSEL element 10. The VCSEL elements 10 constitute a VCSEL element array. The plurality of VCSEL elements 10 are divided into a group (first group) including a plurality of VCSEL elements 10A and a group (second group) including a plurality of VCSEL elements 10B. Each group includes at least two light emitting elements. The VCSEL elements 10A and the VCSEL elements 10B are alternately arranged in each of the row direction and the column direction. From the viewpoint of increasing the density of the VCSEL elements, the VCSEL elements 10A and 10B constituting the VCSEL element array are preferably arranged at equal intervals over the entire VCSEL element array.

The number of VCSEL elements 10 constituting the light emitting device 100 is not limited to 24, and the number of rows and the number of columns constituting the VCSEL element array may be appropriately increased or decreased. Although the VCSEL elements 10A and the VCSEL elements 10B are arranged in the same number in FIG. 1, the number of VCSEL elements 10A and the number of VCSEL elements 10B are not necessarily the same and may be different.

A pad electrode 28A electrically connected to a driving wiring for driving the VCSEL elements 10A and a pad electrode 28B electrically connected to a driving wiring for driving the VCSEL elements 10B are provided around the VCSEL element array. In FIG. 1, the pad electrode 28A and the pad electrode 28B are provided on two adjacent sides of the rectangular region in which the VCSEL element array is arranged, but the pad electrode 28A and the pad electrode 28B may be provided on opposite sides of the rectangular region in which the VCSEL element array is arranged. Alternatively, the pad electrode 28A and the pad electrode 28B may be provided on one side of a rectangular region in which the VCSEL element array is arranged. A plurality of wirings may be connected to each of the pad electrode 28A and the pad electrode 28B.

The VCSEL elements 10A and the VCSEL elements 10B may be provided over a compound semiconductor epitaxial layer 14 grown on a compound semiconductor substrate 12, as illustrated in FIG. 2A and FIG. 2B. An upper portion of the compound semiconductor epitaxial layer 14 is processed into mesa structures 16 having a circular shape in the plan view, and each of the mesa structures 16 constitutes either the VCSEL element 10A or the VCSEL element 10B. The diameter of the mesa structure 16 in the plan view may be, for example, about 20 μm, and the arrangement pitch of the VCSEL elements 10 may be, for example, about 25 μm.

The compound semiconductor epitaxial layer 14 may be provided with a lower distributed Bragg reflector (DBR) layer, a resonator layer including an active layer, and an upper DBR layer (all not illustrated). The upper DBR layer may be provided with a current confinement layer 18 for limiting the path of current to be injected to the active layer. An inner portion surrounded by the current confinement layer 18 serves as a light emitting portion of the VCSEL elements 10A and 10B. The diameter of the light emitting portion in the plan view may be, for example, about 6 μm.

As illustrated in FIG. 2A to FIG. 3C, an insulating layer 20, a driving wiring 22A (first driving wiring), the insulating layer 20, a driving wiring 22B (second driving wiring), and the insulating layer 20 are laminated in this order in the side wall portions of the mesa structures 16 and the region between the mesa structures 16. The driving wiring 22A and the driving wiring 22B are electrically disconnected from each other in the entire area of the light emitting device 100 due to the insulating layer 20 therebetween. In other words, the driving wirings 22A and 22B overlap each other at least in a part in the plan view and are electrically insulated from each other by the insulating layer 20.

As illustrated in FIG. 3A, the driving wiring 22A extends to the upper surface of the mesa structure 16 of the VCSEL element 10A and is electrically connected to the VCSEL element 10A on the upper surface of the mesa structure 16. Although the driving wiring 22A also extends in the vicinity of the upper surface of the mesa structure 16 of the VCSEL element 10B, the insulating layer 20 is provided between the driving wiring 22A and the VCSEL element 10B, and the driving wiring 22A and the VCSEL element 10B are electrically disconnected.

As illustrated in FIG. 3B, the driving wiring 22B extends to the upper surface of the mesa structure 16 of the VCSEL element 10B and is electrically connected to the VCSEL element 10B on the upper surface of the mesa structure 16. Although the driving wiring 22B also extends in the vicinity of the upper surface of the mesa structure 16 of the VCSEL element 10A, the insulating layer 20 is provided between the driving wiring 22B and the VCSEL element 10A, and the driving wiring 22B and the VCSEL element 10A are electrically disconnected.

As described above, the VCSEL elements 10A and 10B are arranged in a square lattice shape and are alternately arranged in each of the row direction and the column direction. Therefore, the two VCSEL elements 10 adjacent to each other at the shortest distance are VCSEL elements 10 belonging to different groups and are connected to different driving wirings 22.

The driving wiring 22A is connected to the peripheral edge portion of the upper surface of the mesa structure 16 of the VCSEL element 10A and has a light emitting port 24A in the central portion of the upper surface of the mesa structure 16. Similarly, the driving wiring 22B is connected to the peripheral edge portion of the upper surface of the mesa structure 16 of the VCSEL element 10B and has a light emitting port 24B in the central portion of the upper surface of the mesa structure 16. The annular regions in the VCSEL elements 10A and 10B illustrated in FIG. 1 are images of the connection portions of the driving wirings 22A and 22B to the upper surface of the mesa structure 16, and the inner contours thereof correspond to the shapes of the light emitting ports 24A and 24B in the plan view. From the viewpoint of efficiently emitting light from the light emitting ports 24A and 24B, the thickness of the insulating layer 20 in the light emitting ports 24A and 24B preferably has a relationship of mλ/2n where λ is the oscillation wavelength, n is the refractive index of the constituent material of the insulating layer 20, and m is an arbitrary natural number.

Each of the driving wiring 22A and the driving wiring 22B is continuously provided over the entire region in which the VCSEL element array is arranged and has a plurality of openings arranged so as not to shield all of the light emitting ports 24A and 24B. That is, each of the driving wiring 22A and the driving wiring 22B is arranged so as to surround the periphery of all the mesa structures 16 constituting the VCSEL elements 10A and 10B. One of the driving wiring 22A and the driving wiring 22B is electrically connected to each of the mesa structures 16. A pad electrode 28A connected to the driving wiring 22A and a pad electrode 28B connected to the driving wiring 22B are provided in the peripheral portion of the VCSEL element array.

By adopting the above-described configuration, the driving wirings 22A and 22B can be arranged to extend to the upper surface of the mesa structure 16 forming the VCSEL elements 10A and 10B, and the cross-sectional areas of the driving wirings 22A and 22B can be increased. The current density can be reduced by increasing the cross-sectional area, so that the current value that can be injected can be further increased.

A common electrode 26 is provided on a surface of the compound semiconductor substrate 12 opposite to a surface on which the compound semiconductor epitaxial layer 14 is provided. When the compound semiconductor substrate 12 is, for example, an n-type semiconductor, the common electrode 26 functions as cathode electrodes of all the VCSEL elements 10A and 10B constituting the VCSEL element array. The connection portion of the driving wiring 22A to the mesa structure 16 functions as an anode electrode of the VCSEL element 10A, and the connection portion of the driving wiring 22B to the mesa structure 16 functions as an anode electrode of the VCSEL element 10B. The compound semiconductor substrate 12 may be a p-type semiconductor, and in this case, the common electrode 26 functions as anode electrodes of all the VCSEL elements 10A and 10B constituting the VCSEL element array. The connection portion of the driving wiring 22A to the mesa structure 16 functions as a cathode electrode of the VCSEL element 10A, and the connection portion of the driving wiring 22B to the mesa structure 16 functions as a cathode electrode of the VCSEL element 10B.

By configuring the light emitting device 100 in this manner, the VCSEL elements 10A and the VCSEL elements 10B may be individually controlled. For example, when a current is injected from only the pad electrode 28A, only the VCSEL elements 10A of the VCSEL elements 10A and 10B emits light, and when a current is injected from only the pad electrode 28B, only the VCSEL elements 10B of the VCSEL elements 10A and 10B emits light. In the case where the VCSEL elements 10A and 10B emit light separately, the number of VCSEL elements 10 connected to one driving wiring 22 is half of that in the case of the VCSEL element array of the conventional configuration, and the current value that may be injected per VCSEL element 10 may be further increased. Accordingly, for example, when the light emitting device 100 is applied to a distance measuring system, the light output per VCSEL element 10 when the total value of the light outputs of the entire VCSEL element array reaches the eye-safe limit becomes higher, and the distance measuring distance range may be increased.

When currents are simultaneously injected from the pad electrodes 28A and 28B, all the VCSEL elements 10A and 10B constituting the VCSEL element array emit light. When the VCSEL elements 10A and 10B are caused to emit light at the same time, since the driving wirings 22A and 22B are separated into two, the number of VCSEL elements 10 connected to each of the driving wirings 22A and 22B is half that in the case of the VCSEL element array of the conventional configuration. As a result, the current value that can be injected per VCSEL element may be made higher, and a two-dimensional VCSEL array with higher output may be realized.

Next, a method of manufacturing the light emitting device 100 according to the present embodiment will be described by taking a VCSEL element that emits light in the 940 nm band as an example.

First, for example, an n-type GaAs substrate is prepared as the compound semiconductor substrate 12. Next, semiconductor layers constituting the lower DBR layer, the resonator layer, the selective oxidation layer, and the upper DBR layer are epitaxially grown over the compound semiconductor substrate 12 by a metal organic chemical vapor deposition (MOCVD) method or a molecular beam epitaxy (MBE) method to form a compound semiconductor epitaxial layer 14. The lower DBR layer may be formed by, for example, repeatedly stacking an n-type GaAs layer and an n-type AlGaAs layer by a predetermined number of layers. The resonator layer may include, for example, an active layer having a multiple quantum well structure including a plurality of InGaAs well layers each sandwiched by AlGaAs barrier layers. The selective oxidation layer may be formed of, for example, a p-type Al_{0.98}GaAs layer. The upper DBR layer may be formed by, for example, repeatedly stacking an n-type GaAs layer and an n-type AlGaAs layer by a predetermined number of layers.

Next, the compound semiconductor epitaxial layer 14 is etched using a photolithography technique and an etching technique until at least the multiple quantum well structure is separated, thereby forming the mesa structures 16 constituting the VCSEL elements 10A and 10B. Next, heat treatment is performed in a water vapor atmosphere to partially selectively oxidize the p-type Al_{0.98}GaAs layer constituting the selective oxidation layer from the side wall portion of the mesa structure 16, thereby forming the current confinement layer 18.

Next, the insulating layer 20 made of, for example, silicon oxide is formed so as to cover the entire surface by, for example, a chemical vapor deposition (CVD) method. Next, openings for connecting the driving wiring 22A and the upper surfaces of the mesa structures 16 of the VCSEL elements 10A are formed in the insulating layer 20 by photolithography and etching. As the insulating layer 20, a dielectric film of silicon nitride, silicon oxynitride, amorphous silicon, aluminum oxide, or the like may be applied in addition to silicon oxide.

Next, the driving wiring 22A and the pad electrode 28A are formed using a lift-off technique. First, a photoresist is formed in a region where the driving wiring 22A and the pad electrode 28A are not arranged by photolithography. Next, a metal layer to be the driving wiring 22A and the pad electrode 28A is formed by a vacuum evaporation method so as to cover the whole. Then, the unnecessary metal layer on the photoresist is removed together with the photoresist to form the driving wiring 22A and the pad electrode 28A.

The metal layer forming the driving wiring 22A and the pad electrode 28A may be formed of, for example, any of Au (gold)/Ti (titanium), Au/Pt (platinum)/Ti, and Au/Ti/Cu (copper)/Ti/Au/Ti. In particular, when it is desired to increase the critical current density, it is preferable that Cu having high electromigration resistance is mainly used. The same applies to the driving wiring 22B and the pad electrode 28B.

Next, the insulating layer 20 made of, for example, silicon oxide is formed so as to cover the entire surface by, for example, CVD method. Next, openings for connecting the driving wiring 22B and the upper surfaces of the mesa structures 16 of the VCSEL elements 10B are formed in the insulating layer 20 by photolithography and etching.

Next, the driving wiring 22B and the pad electrode 28B are formed using a lift-off technique. First, a photoresist is formed in a region where the driving wiring 22B and the pad electrode 28B are not arranged by photolithography. Next, a metal layer to be the driving wiring 22B and the pad electrode 28B is formed by a vacuum evaporation method so as to cover the whole. Next, the driving wiring 22B and the pad electrode 28B are formed by removing the unnecessary metal layer on the photoresist together with the photoresist.

In this way, it is possible to form the driving wiring 22 and the pad electrode 28 on a uniform surface each time the metal vapor evaporation and the lift-off technique are performed.

Next, the insulating layer 20 made of, for example, silicon oxide is formed so as to cover the entire surface by, for example, CVD method. Then, the insulating layer 20 on the pad electrodes 28A and 28B is removed by photolithography and etching to expose the pad electrodes 28A and 28B.

Next, the compound semiconductor substrate 12 is polished and thinned from the side opposite to the side on which the compound semiconductor epitaxial layer 14 is formed, and then a metal layer is deposited on the polished surface of the compound semiconductor substrate 12 by, for example, vacuum evaporation method to form the common electrode 26.

In the present embodiment, the light emitting device having the VCSEL element array in which the VCSEL elements 10 are arranged in a square lattice is exemplified, but the arrangement of the VCSEL elements 10A and 10B is not limited to the square lattice arrangement, and may be, for example, a hexagonal lattice arrangement or a random arrangement.

In addition, in the present embodiment, a light emitting device having the VCSEL element formed of the mesa structure of a compound semiconductor is exemplified, but the VCSEL element does not necessarily need to have the mesa structure and may have a planar structure or a structure in which a mesa structure and a planar structure are combined (not illustrated).

FIG. 4A and FIG. 4B illustrate an example of a light emitting device including the VCSEL elements each having a planar structure. In the planar structure, the insulating layer 20, the driving wirings 22A and 22B, and the pad electrodes 28A and 28B may be arranged on the flat surface of the compound semiconductor epitaxial layer 14 on which the lower DBR layer, the resonator layer, and the upper DBR layer are provided. By providing the isolation structure such as the proton implanted region 32 in the compound semiconductor epitaxial layer 14, it is possible to separate the VCSEL elements 10 adjacent to each other and to confine the current in each VCSEL element 10.

Further, in the present embodiment, the shapes of the mesa structure 16 and the light emitting ports 24 in the plan view are circular but are not necessarily circular. The shapes of the mesa structures 16 and the light emitting ports 24 in the plan view are not particularly limited, and may be, for example, a quadrangular shape as illustrated in FIG. 5 or may be other polygonal shapes. The shapes of the mesa structures 16 and the shapes of the light emitting ports 24 in the plan view are preferably the same but are not necessarily the same.

In the present embodiment, one pad electrode 28A and one pad electrode 28B are provided for each of the plurality of VCSEL elements 10A and the plurality of VCSEL elements 10B, but a plurality of pad electrodes 28A and a plurality of pad electrodes 28B may be provided, for example, as illustrated in FIG. 6. By adopting such a configuration, power may be supplied from the outside to each of the plurality of pad electrodes 28A and 28B through bonding wires or the like, and a light emitting device capable of more uniform current injection may be obtained.

As described above, according to the present embodiment, in a light emitting device having a plurality of individually drivable light emitting element groups, high output and high density of light emitting elements may be realized.

### Second Embodiment

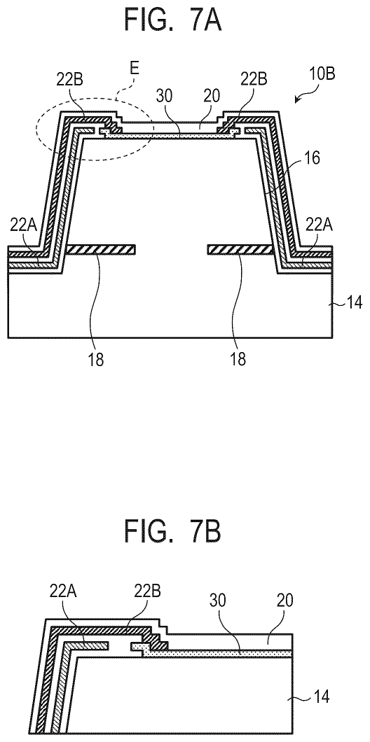

A light emitting device according to a second embodiment of the present invention will be described with reference to FIG. 7A and FIG. 7B. FIG. 7A and FIG. 7B are schematic cross-sectional views illustrating a schematic configuration of the light emitting device according to the present embodiment. The same components as those of the light emitting device according to the first embodiment are denoted by the same reference numerals, and description thereof will be omitted or simplified.

When the diameter of the mesa structure 16 of the VCSEL element 10 is increased in order to further increase the optical power density, the injected carriers are concentrated on the peripheral portion of the light emitting portion, and as a result, a ring-shaped light emission having a large light intensity at the peripheral portion of the light emitting port 24 may be obtained. In the present embodiment, a configuration suitable for realizing more uniform light emission over the entire area of the light emitting portion in a light emitting device having a VCSEL element in which the diameter of the light emitting portion is increased to increase the optical power density will be described. As such a VCSEL element, for example, a VCSEL element 10 in which the diameter of the mesa structure 16 in the plan view is approximately 38 μm, the arrangement pitch of the VCSEL elements 10 is approximately 40 μm, and the diameter of the light emitting portion in the plan view is enlarged to approximately 30 μm may be assumed.

FIG. 7A is a cross-sectional view illustrating a schematic configuration of a VCSEL element 10B of the light emitting device according to the present embodiment, and FIG. 7B is an enlarged cross-sectional view of a region E in FIG. 7A. In the VCSEL element 10B of the present embodiment, as illustrated in FIG. 7A and FIG. 7B, a transparent conductive film 30 having a diameter larger than at least the diameter of the light emitting portion is provided on the upper surface of the mesa structure 16. The transparent conductive film 30 is electrically connected to the mesa structure 16 on the upper surface of the mesa structure 16. The transparent conductive film 30 is insulated from the driving wiring 22A by the insulating layer 20 and is electrically connected to the driving wiring 22B on the upper surface. By configuring the VCSEL element 10B in this manner, carriers injected from the driving wiring 22B are diffused in the transparent conductive film 30 and spread over the entire area of the light emitting portion surrounded by the current confinement layer 18. As a result, it is possible to uniformly emit light over the entire area of the light emitting portion.

The constituent material of the transparent conductive film 30 is not particularly limited as long as it is a conductive material that does not block light emitted from the light emitting portion, and for example, an oxide semiconductor such as indium-tin oxide (ITO), indium oxide, tin oxide, zinc oxide, or indium-gallium-zinc oxide may be applied.

Although FIG. 7A and FIG. 7B illustrate an example in which the configuration of the present embodiment is applied to the VCSEL element 10B, the configuration of the present embodiment may be also applicable to the VCSEL element 10A. In this case, the driving wiring 22A and the transparent conductive film 30 may be electrically connected to each other, and the driving wiring 22B and the transparent conductive film 30 may be insulated from each other by the insulating layer 20.

By adopting the configuration of the present embodiment, in the light emitting device according to the first embodiment, it is possible to realize high output by enlarging the diameter of the light emitting portion.

As described above, according to the present embodiment, in a light emitting device having a plurality of individually drivable light emitting element groups, high output and high density of light emitting elements may be realized.

### Third Embodiment

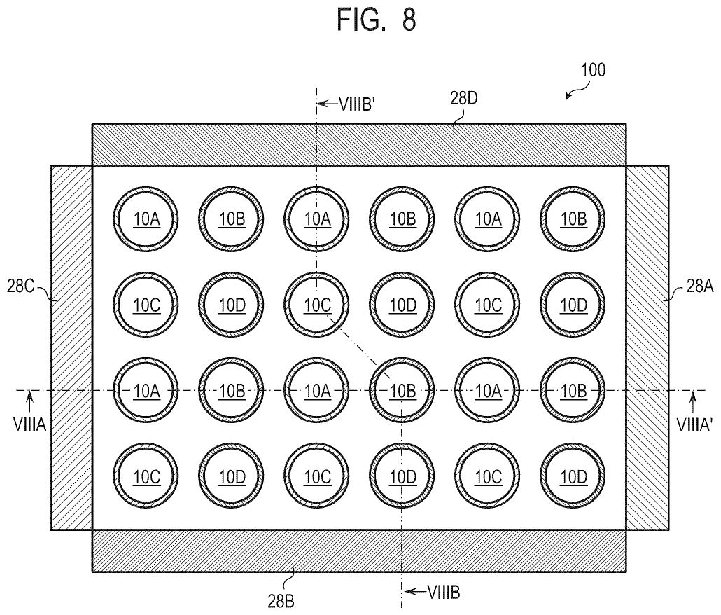

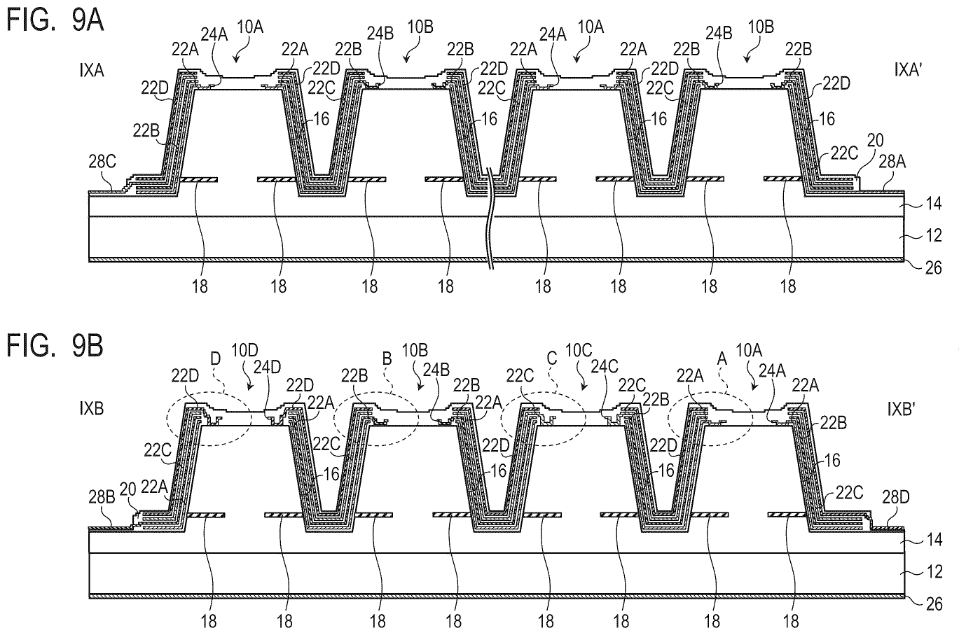

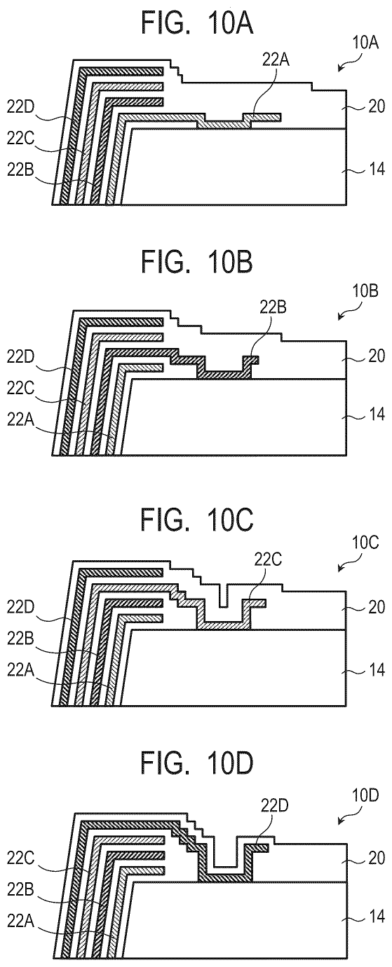

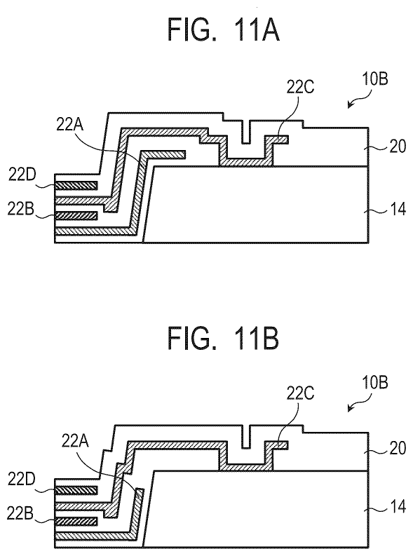

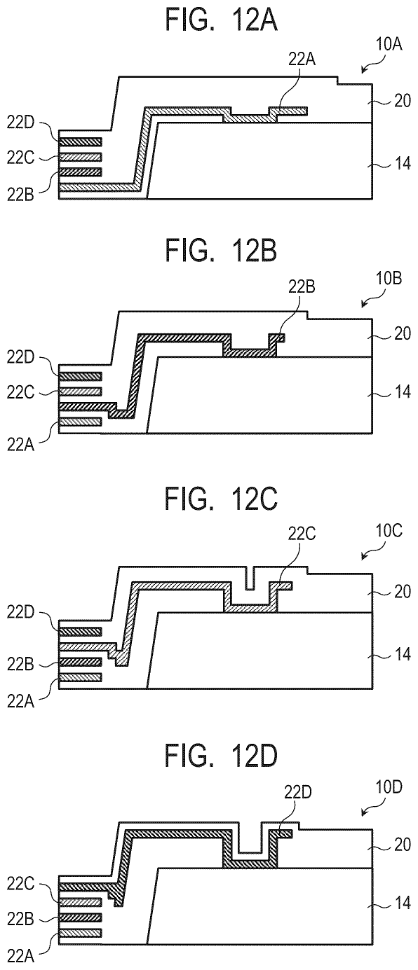

A light emitting device according to a third embodiment of the present invention will be described with reference to FIG. 8 to FIG. 12D. FIG. 8 is a schematic plan view illustrating a schematic configuration of the light emitting device according to the present embodiment. FIG. 9A and FIG. 9B are schematic cross-sectional views illustrating a schematic configuration of the light emitting device according to the present embodiment. FIG. 10A to FIG. 10D are partial cross-sectional views of the light emitting device according to the present embodiment. FIG. 11A to FIG. 12D are schematic cross-sectional views illustrating a schematic configuration of a light emitting device according to a modification of the present embodiment. The same components as those of the light emitting device according to the first or second embodiment are denoted by the same reference numerals, and description thereof will be omitted or simplified.

Although the light emitting device having the VCSEL element 10A and the VCSEL element 10B is described in the first and second embodiments, the number of groups of VCSEL elements 10 that can be independently controlled is not limited to two and may be three or more. In the present embodiment, a light emitting device having four groups of VCSEL elements 10 that can be independently controlled will be described as an example thereof.

Similarly to the first and second embodiments, the light emitting device 100 according to the present embodiment is a surface emitting semiconductor light emitting device in which a plurality of light emitting regions are two-dimensionally arranged. Each of the plurality of light emitting regions is formed of a VCSEL element. FIG. 8 is a plan view of the light emitting device 100 according to the present embodiment as viewed from the light emitting surface side, FIG. 9A is a cross-sectional view taken along line VIIIA-VIIIA′ of FIG. 8, and FIG. 9B is a cross-sectional view taken along line VIIIB-VIIIB′ of FIG. 8. FIG. 10A is an enlarged view of a region A in FIG. 9B, FIG. 10B is an enlarged view of a region B in FIG. 9B, FIG. 10C is an enlarged view of a region C in FIG. 9B, and FIG. 10D is an enlarged view of a region D in FIG. 9B.

FIG. 8 illustrates 24 VCSEL elements 10 arranged in a square lattice of (4rows)×(6 columns) as an example of a plurality of light emitting regions. Each of the 24 circular regions illustrated in FIG. 8 represents a VCSEL element 10. These VCSEL elements 10 constitute a VCSEL element array. The plurality of VCSEL elements 10 include a plurality of VCSEL elements 10A, a plurality of VCSEL elements 10B, a plurality of VCSEL elements 10C, and a plurality of VCSEL elements 10D. The VCSEL elements 10A and the VCSEL elements 10B are alternately arranged in, for example, odd-numbered rows, and the VCSEL elements 10C and the VCSEL elements 10D are alternately arranged in, for example, even-numbered rows. By arranging the four VCSEL elements 10A, 10B, 10C and 10D in the unit block of (2 rows)×(two columns) in this manner, each of the VCSEL elements 10A, 10B, 10C and 10D may be arranged at equal intervals in the VCSEL element array.

The number of VCSEL elements 10 constituting the light emitting device 100 is not limited to 24, and the number of rows and the number of columns constituting the VCSEL element array may be appropriately increased or decreased. Although the same number of VCSEL elements 10A, 10B, 10C and 10D are provided in FIG. 8, the number of VCSEL elements 10A, 10B, 10C and 10D is not necessarily the same and may be different.

Pad electrodes 28A, 28B, 28C and 28D are provided around the VCSEL element array. The pad electrode 28A is electrically connected to a driving wiring for driving the VCSEL elements 10A. The pad electrode 28B is electrically connected to a driving wiring for driving the VCSEL elements 10B. The pad electrode 28C is electrically connected to a driving wiring for driving the VCSEL elements 10C. The pad electrode 28D is electrically connected to a driving wiring for driving the VCSEL elements 10D. In FIG. 8, the pad electrodes 28A, 28B, 28C and 28D are provided on four sides of the rectangular region in which the VCSEL element array is arranged, respectively, but two or more types of pad electrodes 28 may be provided on one side.

The VCSEL elements 10A, 10B, 10C and 10D may be provided in a compound semiconductor epitaxial layer 14 grown on a compound semiconductor substrate 12, as illustrated in FIG. 9A and FIG. 9B. The upper portion of the compound semiconductor epitaxial layer 14 is processed into mesa structures 16 each having a circular shape in the plan view, and each of the mesa structures 16 constitutes any of the VCSEL element 10A, the VCSEL element 10B, the VCSEL element 10C, and the VCSEL element 10D.

As illustrated in FIG. 8 to FIG. 9B, the insulating layer 20, the driving wiring 22A, the insulating layer 20, the driving wiring 22B, the insulating layer 20, the driving wiring 22C, the insulating layer 20, the driving wiring 22D, and the insulating layer 20 are laminated in this order in the side wall portion of the mesa structure 16 and the region between the mesa structures 16. The driving wirings 22A, 22B, 22C and 22D are electrically disconnected from each other in the entire region of the light emitting device 100 by the insulating layer 20 therebetween. In other words, at least a part of the driving wirings 22A, 22B, 22C and 22D overlaps in the plan view, and is electrically insulated from each other by the insulating layer 20.

As illustrated in FIG. 10A, the driving wiring 22A extends to the upper surface of the mesa structure 16 of the VCSEL element 10A and is electrically connected to the VCSEL element 10A on the upper surface of the mesa structure 16. Although the driving wiring 22A also extends in the vicinity of the upper surfaces of the mesa structures 16 of the VCSEL elements 10B, 10C, and 10D, the insulating layer 20 is arranged between the driving wiring 22A and the VCSEL elements 10B, 10C, and 10D. Thus, the driving wiring 22A and the VCSEL elements 10B, 10C, and 10D are electrically disconnected from each other.

As illustrated in FIG. 10B, the driving wiring 22B extends to the upper surface of the mesa structure 16 of the VCSEL element 10B and is electrically connected to the VCSEL element 10B on the upper surface of the mesa structure 16. Although the driving wiring 22B also extends in the vicinity of the upper surfaces of the mesa structures 16 of the VCSEL elements 10A, 10C, and 10D, the insulating layer 20 is arranged between the driving wiring 22B and the VCSEL elements 10A, 10C, and 10D. Thus, the driving wiring 22B and the VCSEL elements 10A, 10C, and 10D are electrically disconnected from each other.

As illustrated in FIG. 10C, the driving wiring 22C extends to the upper surface of the mesa structure 16 of the VCSEL element 10C and is electrically connected to the VCSEL element 10C on the upper surface of the mesa structure 16. Although the driving wiring 22C also extends in the vicinity of the upper surfaces of the mesa structures 16 of the VCSEL elements 10A, 10B, and 10D, the insulating layer 20 is arranged between the driving wiring 22C and the VCSEL elements 10A, 10B, and 10D. Thus, the driving wiring 22C and the VCSEL elements 10A, 10B, and 10D are electrically disconnected from each other.

As illustrated in FIG. 10D, the driving wiring 22D extends to the upper surface of the mesa structure 16 of the VCSEL element 10C and is electrically connected to the VCSEL element 10D on the upper surface of the mesa structure 16. Although the driving wiring 22D also extends in the vicinity of the upper surfaces of the mesa structures 16 of the VCSEL elements 10A, 10B, and 10C, the insulating layer 20 is arranged between the driving wiring 22D and the VCSEL elements 10A, 10B, and 10C. Thus, the driving wiring 22D and the VCSEL elements 10A, 10B, and 10C are electrically disconnected from each other.

The driving wiring 22A is connected to the peripheral edge portion of the upper surface of the mesa structure 16 of the VCSEL element 10A and has a light emitting port 24A of light in the central portion of the upper surface of the mesa structure 16. Similarly, the driving wiring 22B is connected to the peripheral edge portion of the upper surface of the mesa structure 16 of the VCSEL element 10B and has a light emitting port 24B in the central portion of the upper surface of the mesa structure 16. In addition, the driving wiring 22C is connected to the peripheral portion of the upper surface of the mesa structure 16 of the VCSEL element 10C and has a light emitting port 24C in the central portion of the upper surface of the mesa structure 16. In addition, the driving wiring 22D is connected to the peripheral portion of the upper surface of the mesa structure 16 of the VCSEL element 10D and has a light emitting port 24D in the central portion of the upper surface of the mesa structure 16.

Each of the driving wirings 22A, 22B, 22C and 22D is continuously provided over the entire region in which the VCSEL element array is arranged and has a plurality of openings arranged so as not to shield all of the light emitting ports 24A, 24B, 24C and 24D. That is, each of the driving wirings 22A, 22B, 22C and 22D is arranged so as to surround the periphery of all the mesa structures 16 constituting the VCSEL elements 10A, 10B, 10C and 10D. One of the driving wirings 22A, 22B, 22C and 22D is electrically connected to each of the mesa structures 16. A pad electrode 28A connected to the driving wiring 22A, a pad electrode 28B connected to the driving wiring 22B, a pad electrode 28C connected to the driving wiring 22C, and a pad electrode 28D connected to the driving wiring 22D are provided in the peripheral portion of the VCSEL element array.

By adopting the above-described configuration, the driving wirings 22A, 22B, 22C and 22D may be arranged to extend to the upper surface of the mesa structures 16 forming the VCSEL elements 10A, 10B, 10C and 10D. The cross-sectional area of the driving wirings 22A, 22B, 22C and 22D may thereby be increased and the current density may be further reduced, so that the value of the current that can be injected may be further increased.

Although the driving wirings 22A, 22B, 22C and 22D extend to the upper surface of the mesa structure 16 in each of the VCSEL elements 10A, 10B, 10C and 10D in FIG. 9A to FIG. 10D, it is not necessary to extend all the driving wirings 22A, 22B, 22C and 22D to the upper surface of the mesa structure 16. The driving wirings 22A, 22B, 22C and 22D may be configured as illustrated in FIG. 11A to FIG. 12D, for example.

FIG. 11A is a configuration example in which, in the VCSEL element 10C, among the driving wirings 22A, 22B, 22C and 22D, the driving wirings 22A and 22C extend to the upper surface of the mesa structure 16, and the driving wirings 22B and 22D are arranged so as not to overlap the mesa structure 16 in the plan view. In this configuration example, it is possible to selectively widen the cross-sectional areas of the driving wirings 22A and 22C, and it is possible to increase the output of the VCSEL elements 10A and 10C. According to this configuration, in a case where the light emitting device according to the present embodiment is applied to a ranging system, the VCSEL element 10 that emits light may be switched according to the measuring range, such that a high-output light emitting element is used in the long distance measuring range and a low-output light emitting element is used in the short distance measuring range.

FIG. 11B is a configuration example in which, in the VCSEL element 10C, the interconnection extending to the upper surface of the mesa structure 16 is only the driving wiring 22C connected to the mesa structure 16, and the other driving wirings 22A, 22B, and 22D are arranged so as not to extend to the upper surface of the mesa structure 16. In FIG. 11B, the driving wirings 22B and 22D are arranged so as not to overlap the mesa structure 16 in the plan view, and the driving wiring 22A is arranged so as to extend to the middle of the side wall of the mesa structure 16. Two or more of the driving wirings 22A, 22B, and 22D may be arranged so as to extend to the middle of the side wall of the mesa structure 16.

Although FIG. 11A and FIG. 11B illustrate only a configuration example of the VCSEL element 10C, the same configuration as the VCSEL element 10C may be applied to the VCSEL elements 10A, 10B, and 10D.

Alternatively, for example, as illustrated in FIG. 12A to FIG. 12D, in each of the VCSEL elements 10A, 10B, 10C and 10D, the driving wiring 22 extending to the upper surface of the mesa structure 16 may be only the driving wiring 22 electrically connected to the corresponding mesa structure 16.

As described above, according to the present embodiment, in a light emitting device having a plurality of individually drivable light emitting element groups, high output and high density of light emitting elements may be realized.

### Fourth Embodiment

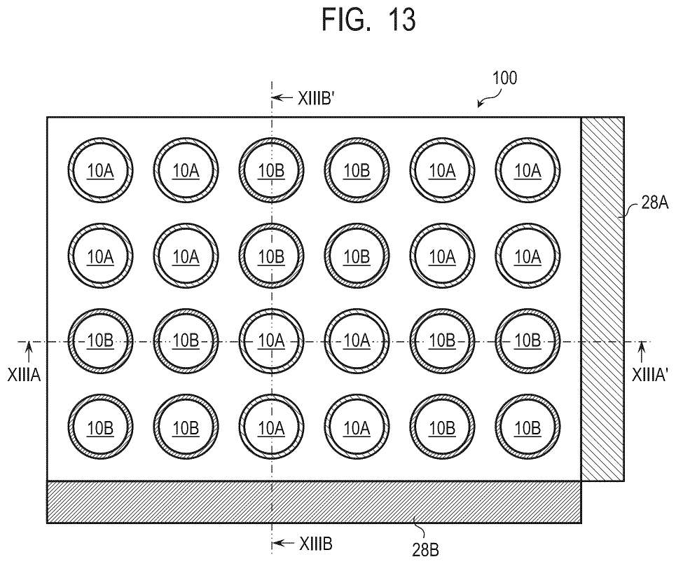

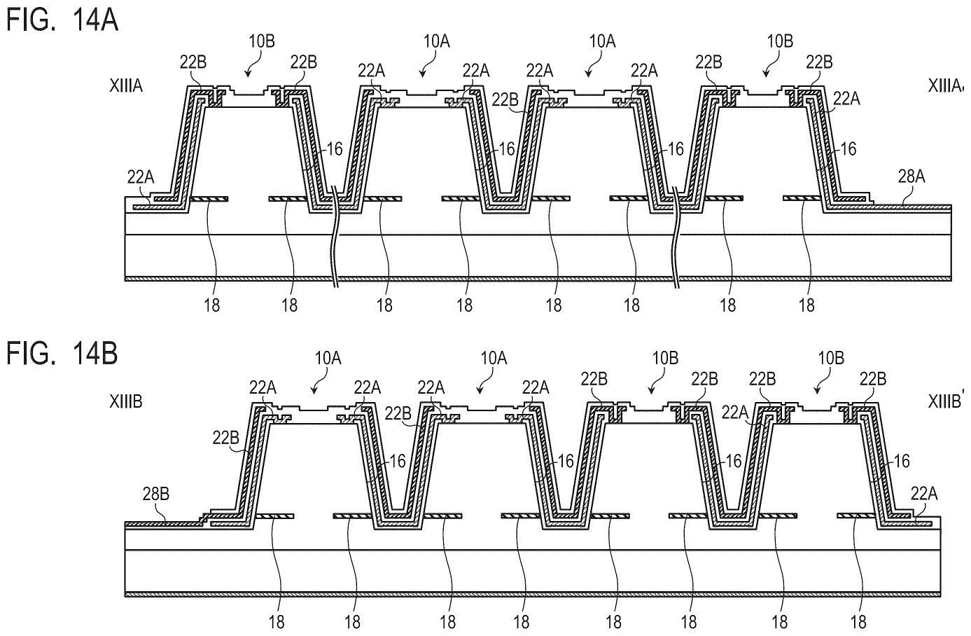

A light emitting device according to a fourth embodiment of the present invention will be described with reference to FIG. 13 to FIG. 14B. FIG. 13 is a schematic plan view illustrating a schematic configuration of the light emitting device according to the present embodiment. FIG. 14A and FIG. 14B are schematic cross-sectional views illustrating a schematic configuration of the light emitting device according to the present embodiment. The same components as those of the light emitting devices according to the first to third embodiments are denoted by the same reference numerals, and description thereof will be omitted or simplified.

Although the VCSEL elements 10A and the VCSEL elements 10B are alternately arranged in each of the row direction and the column direction in the first embodiment, light emitting element blocks arranged in (M-number of rows)×(N-number of columns) may be used as a unit and may be arranged alternately in both the row direction and the column direction. In FIG. 13 to FIG. 14B, a light emitting element block in which the VCSEL elements 10A are arranged in (2 rows)×(2 columns) and a light emitting element block in which the VCSEL elements 10B are arranged in (2 rows)×(2 columns) are alternately arranged in each of the row direction and the column direction. Here, M and N are arbitrary natural numbers, and at least one of M and N is 2 or more. The light emitted from the (M×N) VCSEL elements 10 constituting each light emitting element block may be condensed by one microlens and emitted as one light emitting point.

In the arrangement example of FIG. 13, the light emitting element block including the VCSEL elements 10A and the light emitting element block including the VCSEL elements 10B are arranged in a square lattice shape as illustrated. In this case, the VCSEL elements included in the two light emitting element blocks adjacent to each other with the shortest distance are VCSEL elements belonging to different groups, and are connected to different driving wirings 22.

When three or more types of VCSEL elements 10 are included as in the third embodiment, different types of light emitting element blocks each including the same type of VCSEL elements 10 may be periodically arranged in each of the row direction and the column direction.

Since the light output per light emitting point is increased by configuring the light emitting device so that the plurality of VCSEL elements 10 form one light emitting point, for example, when the light emitting device according to the present embodiment is applied to a distance measuring system, it is possible to realize a distance measuring system having a long-distance measuring range.

As described above, according to the present embodiment, in a light emitting device having a plurality of individually drivable light emitting element groups, high output and high density of light emitting elements may be realized.

### Fifth Embodiment

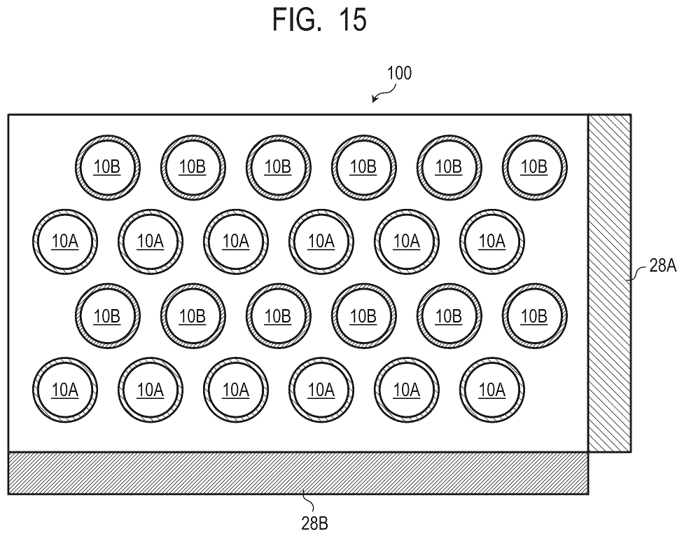

A light emitting device according to a fifth embodiment of the present invention will be described with reference to FIG. 15. FIG. 15 is a schematic plan view illustrating a schematic configuration of the light emitting device according to the present embodiment. The same components as those of the light emitting devices according to the first to fourth embodiments are denoted by the same reference numerals, and description thereof will be omitted or simplified.

In the first embodiment, the VCSEL elements 10A and the VCSEL elements 10B are alternately arranged in each of the row direction and the column direction, but the VCSEL elements 10A and the VCSEL elements 10B may be alternately arranged every M-number of rows or every N-number of columns. Here, M and N are arbitrary natural numbers.

FIG. 15 illustrates a configuration example in which VCSEL elements 10A and VCSEL elements 10B are alternately arranged for each row. Each row includes only one of the VCSEL elements 10A and 10B.

In the case where three or more types of VCSEL elements 10 are included as in the third embodiment, three or more types of light emitting element blocks each including the same type of VCSEL elements 10 may be periodically arranged in the column direction or the row direction.

Also in the arrangement example of the present embodiment, the VCSEL elements included in the two light emitting element blocks adjacent to each other with the shortest distance are VCSEL elements belonging to different groups, and are connected to different driving wirings 22.

As described above, according to the present embodiment, in a light emitting device having a plurality of individually drivable light emitting element groups, high output and high density of light emitting elements may be realized.

### Sixth Embodiment

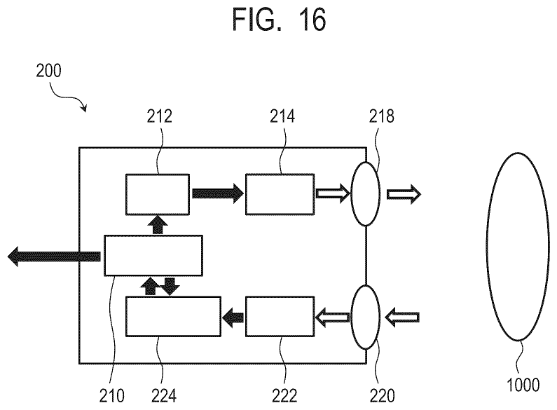

A ranging device according to a sixth embodiment of the present invention will be described with reference to FIG. 16. FIG. 16 is a block diagram illustrating a schematic configuration of a ranging device according to the present embodiment.

The ranging device 200 according to the present embodiment is a ranging device (LiDAR device) in which the light emitting device 100 according to any one of the first to fifth embodiments is applied to a light source unit. The ranging device 200 may include a control unit 210, a surface emitting laser array driver 212, a surface emitting laser array 214, a light emitting side optical system 218, a light receiving side optical system 220, an image sensor 222, and a distance data processing unit 224.

The surface emitting laser array 214 is a package on which the light emitting device 100 according to any one of the first to fifth embodiments is mounted. The surface emitting laser array driver 212 is a driving unit that receives a driving signal from the control unit 210, generates a driving current for oscillating the surface emitting laser array 214, and outputs the driving current to the surface emitting laser array 214. The surface emitting laser array 214 and the surface emitting laser array driver 212 are not necessarily separate components, and the surface emitting laser array 214 may have the function of the surface emitting laser array driver 212.

The light emitting side optical system 218 is an optical system that emits laser light generated by the surface emitting laser array 214 toward a range to be measured. The light receiving side optical system 220 is an optical system that guides the laser beam reflected by the measurement target 1000 to the image sensor 222. In FIG. 16, the light emitting side optical system 218 and the light receiving side optical system 220 are represented by one convex lens-shaped member, but they are not composed of only one convex lens-shaped member but are composed of a lens group in which a plurality of lenses are combined.

The image sensor 222 is a photoelectric conversion device in which a plurality of pixels including photoelectric conversion units are arranged in a two-dimensional array and is a light receiving device that outputs an electric signal according to incident light. The image sensor 222 may be, for example, an imaging device such as a complementary metal-oxide semiconductor (CMOS) image sensor or a single photon avalanche diode (SPAD) image sensor. The distance data processing unit 224 has a function as a distance information acquisition unit that generates and outputs information related to the distance to the measurement target 1000 present in the distance measurement target range based on the signal from the image sensor 222. The distance data processing unit 224 is electrically connected to the image sensor 222 and may be arranged in the same package as the image sensor 222 or may be arranged in a package different from the image sensor 222.

The control unit 210 is configured by a microcomputer, an information processing device including a logic circuit or the like and has a function as a central processing device that governs operations in the ranging device 200, such as operation control of each unit and various arithmetic processing.

Next, the operation of the ranging device according to the present embodiment will be described with reference to FIG. 16.

First, the control unit 210 outputs a drive signal to the surface emitting laser array driver 212. The surface emitting laser array driver 212 receives the drive signal from the control unit 210 and injects a current of a predetermined current value into the surface emitting laser array 214. As a result, the surface emitting laser array 214 oscillates, and laser light is output from the surface emitting laser array 214.

The laser light generated by the surface emitting laser array 214 is emitted toward the range to be measured by the light emitting side optical system 218. Among the laser beams irradiated to the measurement target 1000 in the range to be measured, the laser beam reflected by the measurement target 1000 and incident on the light receiving side optical system 220 is guided to the image sensor 222 by the light receiving side optical system 220.

Each pixel of the image sensor 222 generates an electrical signal pulse according to the timing of incidence of the laser beam. The electric signal pulse generated by the image sensor 222 is input to the distance data processing unit 224.

The distance data processing unit 224 generates information on the distance to the measurement target 1000 along the light propagation direction based on the reception timing of the electric signal pulse output from the image sensor 222. For example, the information on the distance to the measurement target 1000 is generated based on the time difference between the timing at which the light is emitted from the surface emitting laser array 214 and the timing at which the light is received by the image sensor 222. By calculating distance information based on electric signal pulses output from each pixel of the image sensor 222, it is possible to acquire three-dimensional information of the measurement target 1000.

The ranging device 200 according to the present embodiment is applicable to, for example in the field of automobiles, a control device for performing control so as not to collide with another vehicle, a control device for performing control so as to follow another vehicle, perform automatic driving, and the like. The ranging device 200 according to the present embodiment is applicable not only to an automobile but also to other moving objects (moving device) such as a ship, an aircraft, or an industrial robot, a moving object detection system, and the like. The ranging device 200 according to the present embodiment may be widely applied to an equipment that uses information of an object recognized three-dimensionally, including distance information. These moving objects may be configured to include the ranging device according to the present embodiment and a control unit that controls the moving object based on the information on the distance acquired by the ranging device.

The three-dimensional information including the depth that can be acquired by the ranging device 200 according to the present embodiment may also be used in an image capturing device, an image processing device, a display device, or the like. For example, by using the three-dimensional information acquired by the ranging device 200 according to the present embodiment, it is possible to display a virtual object on an image of the real world without a sense of discomfort. In addition, by storing the three-dimensional information together with the image information, it is also possible to correct the blur or the like of the photographed image after photographing.

### Seventh Embodiment

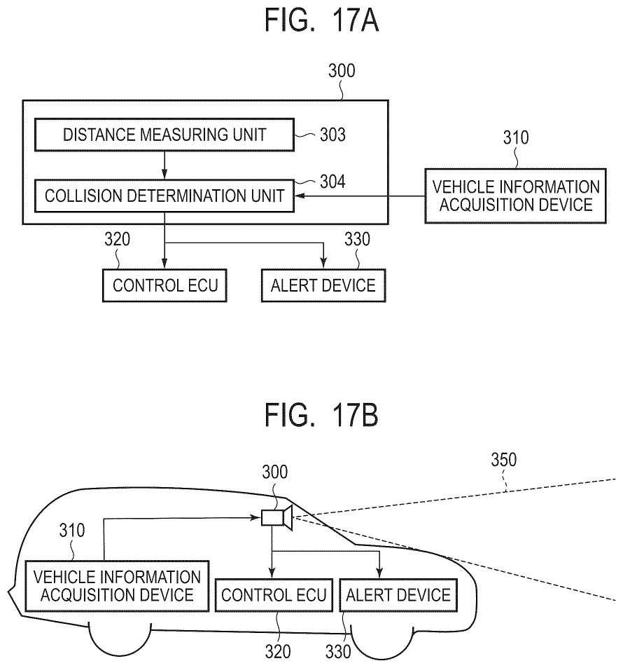

A moving object according to a seventh embodiment of the present invention will be described with reference to FIG. 17A and FIG. 17B. FIG. 17A and FIG. 17B are block diagrams illustrating a configuration example of a moving object according to the present embodiment.

FIG. 17A illustrates a configuration example of an equipment mounted on a vehicle as an on-vehicle camera. The equipment 300 includes a distance measuring unit 303 that measures a distance to a distance measurement target, and a collision determination unit 304 that determines whether or not there is a possibility of collision based on the distance measured by the distance measuring unit 303. The distance measuring unit 303 may be configured by, for example, the ranging device 200 described in the sixth embodiment. Here, the distance measuring unit 303 is an example of a distance information acquisition unit that acquires distance information to the distance measurement target. That is, the distance information is information related to the distance to the distance measurement target or the like.

The equipment 300 is connected to the vehicle information acquisition device 310 and may acquire vehicle information such as a vehicle speed, a yaw rate, and a steering angle. In addition, a control ECU 320, which is a control device that outputs a control signal for generating a braking force to the vehicle based on the determination result of the collision determination unit 304, is connected to the equipment 300. The equipment 300 is also connected to an alert device 330 that issues an alert to the driver based on the determination result of the collision determination unit 304. For example, when the determination result of the collision determination unit 304 indicates that the possibility of collision is high, the control ECU 320 performs vehicle control to avoid collision and reduce damage by applying a brake, returning an accelerator, suppressing engine output, or the like. The alert device 330 gives an alert to the user by sounding an alarm such as a sound, displaying alert information on a screen of a car navigation system or the like, giving vibration to a seat belt or a steering wheel, or the like. These devices of the equipment 300 function as a moving object control unit that controls the operation of controlling the vehicle as described above.

In the present embodiment, the distance to the surroundings of the vehicle, for example, the front or the rear is measured by the equipment 300. FIG. 17B illustrates the equipment 300 in the case of distance measurement in front of the vehicle (distance measurement range 350). The vehicle information acquisition device 310 serving as the distance measurement control unit sends an instruction to the equipment 300 or the distance measuring unit 303 to perform the distance measurement operation. With such a configuration, the accuracy of distance measurement may be further improved.

In the above description, an example in which control is performed so as not to collide with another vehicle has been described, but the present invention is also applicable to control in which automatic driving is performed so as to follow another vehicle, control in which automatic driving is performed so as not to protrude from a lane, and the like. Furthermore, the equipment is not limited to vehicles such as automobiles, and may be applied to, the other moving objects (mobile devices), for example, ships, aircrafts, artificial satellites, industrial robots, consumer robots, and the like. In addition, the present invention is not limited to the moving object and may be widely applied to the equipment utilizing object recognition or biological recognition, such as intelligent transport systems (ITS), monitoring systems, and the like.

### Modified Embodiments

The present invention is not limited to the above-described embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present invention.

In the above-described second to fifth embodiments, the shapes of the mesa structures 16 and the light emitting ports 24 in the plan view are circular, but are not necessarily circular, and may be quadrangular or other polygonal shapes as described as a modification of the first embodiment. The VCSEL element does not necessarily have a mesa structure and may have a planar structure or a structure in which a mesa structure and a planar structure are combined. Also in the third to fifth embodiments, as described in the second embodiment, the transparent conductive film 30 may be arranged on the upper surface of the mesa structures 16.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024- 016927, filed Feb. 7, 2024, which is hereby incorporated by reference herein in its entirety.

What is claimed is:

1. A light emitting device comprising:
a plurality of light emitting elements; and
a plurality of driving wirings configured to drive the plurality of light emitting elements,
wherein the plurality of light emitting elements are divided into a plurality of groups each including at least two light emitting elements,
wherein the plurality of driving wirings are provided corresponding to the plurality of groups,
wherein the plurality of driving wirings overlap each other at least a part thereof in a plan view, and is electrically separated from each other by an insulating layer,
wherein each of the plurality of driving wirings is electrically connected to light emitting elements belonging to the corresponding group among the plurality of groups on upper surfaces of the light emitting elements,
wherein a first driving wiring among the plurality of driving wirings is electrically connected to light emitting elements belonging to a first group among the plurality of groups, and is not electrically connected to light emitting elements belonging to a second group among the plurality of groups,
wherein a second driving wiring among the plurality of driving wirings is not electrically connected to the light emitting elements belonging to the first group, and is electrically connected to the light emitting elements belonging to the second group, and
wherein the first driving wiring extends over the upper surfaces of the light emitting elements belonging to the second group.

2. The light emitting device according to claim 1 further comprising: a transparent conductive film provided on the upper surface of each of the plurality of light emitting elements.

3. The light emitting device according to claim 2, wherein each of the plurality of driving wirings is electrically connected to each of the light emitting elements belonging to the corresponding group through the transparent conductive film.

4. The light emitting device according to claim 3, wherein the transparent conductive film includes indium tin oxide.

5. The light emitting device according to claim 1, wherein the light emitting element has a mesa structure.

6. The light emitting device according to claim 1, wherein the light emitting element has a planar structure.

7. The light emitting device according to claim 1, wherein each of the plurality of driving wirings are continuously provided over an entire region in which the plurality of light emitting elements are arranged and have an opening in a portion of a light emitting port of each of the plurality of light emitting elements.

8. The light emitting device according to claim 1, wherein each of the plurality of driving wirings are arranged so as to surround the periphery of each of the plurality of light emitting elements.

9. The light emitting device according to claim 1,
wherein the plurality of light emitting elements are arranged in a square lattice, and
wherein each of the two light emitting elements adjacent to each other at the shortest distance are connected to different driving wirings.

10. The light emitting device according to claim 1,
wherein the plurality of light emitting elements are divided into a plurality of light emitting element blocks each including a predetermined number of the light emitting elements adjacent to each other,
wherein the light emitting elements included in the same light emitting element block are connected to the same driving wiring, and
wherein the light emitting element included in one light emitting element block and the light emitting element included in another light emitting element block arranged adjacent to the one light emitting element block at the shortest distance are connected to different driving wirings.

11. The light emitting device according to claim 10, wherein the plurality of light emitting element blocks are arranged in a square lattice.

12. The light emitting device according to claim 10, wherein each of the plurality of light emitting element blocks includes a predetermined number of the light emitting elements arranged in a line.

13. The light emitting device according to claim 1 further comprising: a plurality of pad electrodes connected to the plurality of driving wirings,
wherein two or more pad electrodes are provided corresponding to each of the plurality of driving wirings.

14. The light emitting device according to claim 13, wherein the plurality of pad electrodes are arranged around a region in which the plurality of light emitting elements are arranged.

15. The light emitting device according to claim 1, wherein each of the plurality of light emitting elements is a VCSEL element.

16. The light emitting device according to claim 1, wherein the plurality of light emitting elements are arranged at equal intervals.

17. A light emitting device comprising:
a plurality of light emitting elements; and
a plurality of driving wirings configured to drive the plurality of light emitting elements,
wherein the plurality of light emitting elements are divided into a plurality of groups each including at least two light emitting elements,
wherein the plurality of driving wirings are provided corresponding to the plurality of groups,
wherein the plurality of driving wirings overlap each other at least a part thereof in a plan view, and is electrically separated from each other by an insulating layer,
wherein each of the plurality of driving wirings is electrically connected to light emitting elements belonging to the corresponding group among the plurality of groups on upper surfaces of the light emitting elements,
wherein a first driving wiring among the plurality of driving wirings is electrically connected to light emitting elements belonging to a first group among the plurality of groups, and is not electrically connected to light emitting elements belonging to a second group among the plurality of groups,
wherein a second drive wiring among the plurality of driving wirings is not electrically connected to the light emitting elements belonging to the first group, and is electrically connected to the light emitting elements belonging to the second group, and
wherein the rest driving wirings other than the second driving wiring among the plurality of driving wirings extend over the upper surfaces of the light emitting elements belonging to the second group.

18. The light emitting device according to claim 17 further comprising: a transparent conductive film provided on the upper surface of each of the plurality of light emitting elements.

19. The light emitting device according to claim 18, wherein each of the plurality of driving wirings is electrically connected to each of the light emitting elements belonging to the corresponding group through the transparent conductive film.

20. The light emitting device according to claim 19, wherein the transparent conductive film includes indium tin oxide.

21. The light emitting device according to claim 17, wherein the light emitting element has a mesa structure.

22. The light emitting device according to claim 17, wherein the light emitting element has a planar structure.

23. The light emitting device according to claim 17, wherein each of the plurality of driving wirings is continuously provided over an entire region in which the plurality of light emitting elements are arranged and has an opening in a portion of a light emitting port of each of the plurality of light emitting elements.

24. The light emitting device according to claim 17, wherein each of the plurality of driving wirings is arranged so as to surround the periphery of each of the plurality of light emitting elements.

25. The light emitting device according to claim 17,
wherein the plurality of light emitting elements are arranged in a square lattice, and
wherein each of the two light emitting elements adjacent to each other at the shortest distance are connected to different driving wirings.

26. The light emitting device according to claim 17,
wherein the plurality of light emitting elements are divided into a plurality of light emitting element blocks each including a predetermined number of the light emitting elements adjacent to each other,
wherein the light emitting elements included in the same light emitting element block are connected to the same driving wiring, and
wherein the light emitting element included in one light emitting element block and the light emitting element included in another light emitting element block arranged adjacent to the one light emitting element block at the shortest distance are connected to different driving wirings.

27. The light emitting device according to claim 26, wherein the plurality of light emitting element blocks are arranged in a square lattice.

28. The light emitting device according to claim 26, wherein each of the plurality of light emitting element blocks includes a predetermined number of light emitting elements arranged in a line.

29. The light emitting device according to claim 17 further comprising: a plurality of pad electrodes connected to the plurality of driving wirings,
wherein two or more pad electrodes are provided corresponding to each of the plurality of driving wirings.

30. The light emitting device according to claim 26, wherein the plurality of pad electrodes are arranged around a region in which the plurality of light emitting elements are arranged.

31. The light emitting device according to claim 17, wherein each of the plurality of light emitting elements is a VCSEL element.

32. The light emitting device according to claim 17, wherein the plurality of light emitting elements are arranged at equal intervals.

33. A ranging device comprising:
the light emitting device according to claim 1;
a light receiving device configured to receive light emitted from the light emitting device and reflected by an object to be measured; and
a distance information acquisition unit configured to acquire information on a distance to the object to be measured based on a time difference between a timing at which light is emitted from the light emitting device and a timing at which the light receiving device receives light.

34. A ranging device comprising:
the light emitting device according to claim 17;
a light receiving device configured to receive light emitted from the light emitting device and reflected by an object to be measured; and
a distance information acquisition unit configured to acquire information on a distance to the object to be measured based on a time difference between a timing at which light is emitted from the light emitting device and a timing at which the light receiving device receives light.

35. A moving object comprising:
the ranging device according to claim 33, and
a control device configured to control the moving object based on distance information acquired by the ranging device.

36. A moving object comprising:
the ranging device according to claim 34, and
a control device configured to control the moving object based on distance information acquired by the ranging device.
